(19) United States
(12) Patent Application Publication
(10) Pub. No.: US 2023/0407123 A1
(43) Pub. Date: Dec. 21, 2023

(54) FUNCTIONAL NANOINKS FOR FULLY PRINTED PASSIVE AND ACTIVE RESISTIVE SWITCHING DEVICES

(71) Applicant: Nikolay Frick, Cary, NC (US)

(72) Inventor: Nikolay Frick, Cary, NC (US)

(21) Appl. No.: 18/317,905

(22) Filed: May 15, 2023

Related U.S. Application Data
(60) Provisional application No. 63/352,882, filed on Jun. 16, 2022.

(51) Int. Cl. C09D 11/52; C09D 11/322; C09D 11/36; C09D 11/037; C09D 11/106; C09D 11/033; H03K 17/56; B41M 5/00

(52) U.S. Cl. CPC C09D 11/52; C09D 11/322; C09D 11/36; C09D 11/037; C09D 11/106; C09D 11/033; H03K 17/56; B41M 5/00

(57) ABSTRACT

Nanoparticle ink compositions are disclosed. The nanoparticle ink compositions are printable. The nanoparticle ink compositions include a highly resistive nanoparticle and a conductive nanoparticle in a carrier. Methods of manufacturing microscale assemblies are also disclosed. The methods include printing at least one layer of a nanoparticle ink composition onto a substrate adjacent at least one metallic or conductive electrode. The microscale assemblies form at least one component of a neuromorphic computing chip, a photonic or chemical sensor, or a quantum computation chip. The microscale assemblies exhibit properties of a nanoscale assembly. Switching matrix to produce wide range of circuit configurations is disclosed.

### CROSS-REFERENCES TO RELATED PATENT APPLICATIONS

This application claims the benefit of priority under 35 U.S.C. Section 119(e) to the U.S. patent application Ser. No. 63/352,882, filed on Jun. 16, 2022, the entire content of which is incorporated herein by reference.

### STATEMENT REGARDING FEDERALLY SPONSORED RESEARCH OR DEVELOPMENT

Not Applicable.

### REFERENCE TO SEQUENCE LISTING, A TABLE, OR A COMPUTER PROGRAM LISTING COMPACT DISK APPENDIX

Not Applicable.

### FIELD

The present invention is related generally to the field of nanotechnology and artificial intelligence hardware and, more specifically, to functional nanoinks that are useful for manufacturing switching and memory devices and hardware to construct functional circuits with them.

### BACKGROUND

Many kinds of conductive metallic inks are available in the form of metallic particle colloids or reactive organic complexes that can be used with inkjet, flexography, gravure, lithography, or screen printing. However, these conductive inks are made for connecting functional elements or regions of the circuits and do not exhibit any functional properties like sensing, memory, or computing. There is a much smaller variety of functional inks that can be used with conventional printing techniques, for example, semiconductor inks (such as poly(3,4-ethylenedioxythiophene), polystyrene sulfonate (PEDOT:PSS), and custom perovskites). However, these semiconductor inks are difficult to use due to a lack of compatibility with printing equipment or insufficient stability.

Memristor is one of promising electronic components that can be used for memory and computing applications due to its ability to store the history of its conductive states in the form of instantaneous resistance. Therefore, memristive inks may enable simpler manufacturing and production of functional, lightweight memory and computing devices suitable for wearable and flexible electronics applications. However, currently, there are no commercially available memristive ink solutions for printed electronics that would be compatible with complementary metal-oxide semiconductor (CMOS) process. Accordingly, there is a need for improved conductive, semiconducting, and memristive inks.

### SUMMARY

In accordance with one aspect, there is provided a composition comprising a highly resistive nanoparticle and a conductive nanoparticle in a carrier, wherein the composition is formulated as an ink.

In some embodiments, at least one of the highly resistive nanoparticle and the conductive nanoparticle is present in an amount below a percolation threshold of the composition.

In some embodiments, the highly resistive nanoparticle and the conductive nanoparticle are each present in an amount below the percolation threshold of the composition.

In some embodiments, the composition further comprises an insulating binder material.

In some embodiments, the highly resistive nanoparticle and the conductive nanoparticle are each independently in the form of a rod, wire, sphere, crystalline particle, or amorphous particle.

In accordance with another aspect, there is provided a method of manufacturing a microscale assembly. The method may comprise printing at least one layer of the composition onto a substrate adjacent at least one conductive electrode to form the microscale assembly.

In some embodiments, the method comprises printing the at least one layer of the composition between two conductive electrodes.

In some embodiments, the material can form a 3D structure that is penetrated by a conductive multielectrode array.

In some embodiments, the substrate is a non-conductive material selected from plastic, silicon, silicone, glass, or polyimide.

In some embodiments, the substrate is a conductive coated glass.

In some embodiments, the microscale assembly forms at least one component of a neuromorphic computing chip, a photonic or chemical sensor, or a quantum computation chip.

In some embodiments, the assembly has a thickness of between about 0.1 μm and about 99 μm.

In some embodiments, the assembly experiences resistive switching responsive to an applied electric field having a voltage of less than 30 volts.

In some embodiments, the assembly has a thickness of between about 10 μm and about 99 μm and experiences resistive switching responsive to an applied electric field having a voltage of less than 10 volts.

In some embodiments, the assembly is a one-dimensional assembly.

In some embodiments, the assembly is a two-dimensional assembly.

In some embodiments, the assembly is a three-dimensional assembly.

In some embodiments there is an array of electrically conductive posts that can be used to connect to the inks deposited on top.

In some embodiments these posts are connected to a unique switching matrix with three switches per crossing that allow assembly of computing elements.

In some embodiment these circuits can be used to assemble an XOR computing unit or an artificial neural network.

### BRIEF DESCRIPTION OF THE DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a schematic drawing showing a cross-sectional side view and a top view of a layered assembly, according to one embodiment;

FIG. 2 is a schematic drawing showing exemplary nanoink compositions, according to one embodiment;

FIG. 3 is a graph showing percolation probability as a result of volume/surface fraction;

FIG. 4 is a schematic diagram showing exemplary layered constructs, in accordance with certain embodiments;

FIG. 5 includes graphs showing resistive switch voltage of conductive inks, in accordance with one embodiment;

FIG. 6 includes graphs showing voltage driven and current driven resistive switching, in accordance with one embodiment;

FIG. 7 shows a variant of a switching matrix with one electrically conducting post per crossing (left) or a whole memristive device at the intersection (right);

FIG. 8 shows parallel, series and selective control circuits produced with switching matrix and memristors and other auxiliary elements;

FIG. 9 shows the smallest memristor circuit which can compute XOR function with an equivalent neuron circuit and the resulting simulations of the output being converted into a linearly separable function; and

FIG. 10 shows an example of a neural network produced and it's circuitry produced with the switching matrix.

### DETAILED DESCRIPTION

### A. Terms and Definitions

The terms used herein are generally defined according to the common and customary usage in the art and will be understood as such by those having ordinary skill in the art. In case of any dispute or discrepancy as to the terms, the definitions given below are to be used as default.

The scope of the term “compositions” as used herein is intended to be inclusive of both true solutions and colloid dispersions.

The term “nanoink” as used herein, is defined as a kind of a liquid colloid, suspension or dispersion that is comprised of nanoparticles dispersed in an organic solvent (carrier) that might have dispersants, stabilizers, encapsulants, rheology optimizers, or a vehicle.

The term “nanoparticle” as used herein is defined as a solid particle of matter having the size of at least one dimensions that is between about 1 and about 100 nanometers.

The term “highly resistive nanoparticle” as used herein is defined as an insulator or semiconductor nanoscale material that can change conductivity into a “lower resistive state” via ionic or oxygen vacancy transport or metal/insulator phase change. The driving force for switching between high resistivity and low resistivity results from ionic motion, electric field, chemical potential or Joule heating. The typical resistance of the highly resistive nanoparticles can vary significantly depending on the material, size, shape, and doping level of the nanoparticles.

Semiconductive nanoparticles, such as metal oxides (e.g., TiO₂, ZnO, TiO₂, HfO₂), and sulfides/selenides (e.g., Ag₂S, Cu₂S, Ag₂Se), and carbon-based nanomaterials (e.g., graphene, carbon nanotubes), exhibit unique electrical properties due to their nanoscale dimensions and large surface-to-volume ratio. The resistance of these nanoparticles can be tuned through various factors, including size, doping with other elements, and surface functionalization. However rough approximation of highly resistive state can be from 10s of kOhms to several GOhms.

The term “conductive nanoparticle” as used herein is defined as a metallic with conductivities from 10-5 to 10-8 Ohm·cm. Organic conductive compounds PEDOT:PSS that exhibit relatively small resistivity from 1-3 to 10 Ohm·cm or even greater, up to 1000 Ohm·cm. In our case semi-conductive nanoparticles with conductive filaments, such as Ag₂S, Cu₂S, HfO₂ etc. or phase transition materials, such as VO₂, NbO₂ etc. would exhibit nearly conductive properties in low conductivity regime as in the metallic phase with values usually between 10\hat{ }(−4) to 10\hat{ }(−6) Ω·cm.

The term “carrier” as used herein is defined as a liquid forming the continuous phase in which a solute is dissolved or dispersed to form either a solution or a colloid dispersion, respectively.

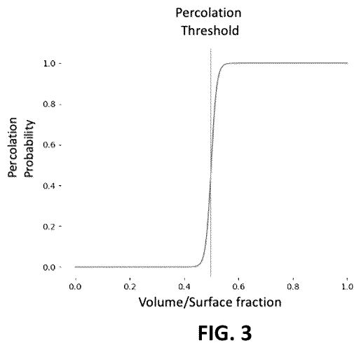

The term “percolation threshold” as used herein is defined as the percolation probability as a function of normalized volume/surface fraction of components when the percolation probability is 0.5 or 50%, as shown by FIG. 3 and discussed in more detail below.

### Embodiments

The disclosure relates to nanoink manufacturing. The nanoinks disclosed herein may be used for manufacture of memristors and neuristors for neuromorphic computing devices. Neuromorphic computing devices are typically made of passive elements called memristors (or resistive switches or synaptors) and/or active devices that simulate the action potential of biological neurons, neuristors (such as, Josephson-junction devices, which are used for constructing gates in some types of solid-state quantum computers).

The nanoinks disclosed herein may also be used in the manufacture of photonic or chemical sensors. Typically, neuromorphic devices are manufactured with silicon technology to simplify integration with complementary metal-oxide semiconductor (CMOS) manufacturing. However, lithography on silicon is difficult, time-consuming, and impractical for neuromorphic applications. First, the conventional methods are generally impractical due to a complex technological process requiring a cleanroom, lithography equipment, wafer inspection, profilometry, ellipsometry, and thorough testing. Second, the conventional methods may be too tedious for the desired results. In particular, because the manufactured neuromorphic devices are designed to mimic brain activity, the organization and repeatability of devices made with silicon technology have negligible impact on performance. Additionally, neuromorphic devices, including quantum computing devices, typically do not require dense integration of billions of elements. Thus, neuromorphic computing chips may permit variance in the device parameters and allow more rough manufacturing processes, such as printing.

The disclosure provides a method to manufacture or produce devices, such as, sensing, neuromorphic, and/or quantum computation devices, that can be easily integrated with CMOS technology. Also, the manufacture methods disclosed herein may allow seamless integration into wearable electronics infrastructure.

Disclosed herein are nanoparticle inks, also referred to as “nanoink(s).” Nanoparticles may be conveniently deposited in the form of inks. The nanoink may be used as a media for printing. The nanoinks disclosed herein may be tailored for development of passive or active functionality, for example, passive linear ohmic conductivity. The inks disclosed herein may provide conductive, semiconductive, and/or memresistive properties. Memristive properties include, for example, the ability of the ink to change conductivity based on the magnitude and direction of applied field or the amount of current passed in one way or another.

The nanoinks may be printed onto a substrate to form an assembly. In some embodiments, the nanoinks may be printed to produce a layered construct, forming an assembly having microscale dimensions. The microscale dimensioned constructs may beneficially exhibit properties or features typically exhibited by nanoscale dimensioned devices. The microscale assemblies or devices may have dimensions in a range of between about 0.1 μm and about 1000 μm, for example, between about 0.1 μm and about 10 μm, or between about 1 μm and about 10 μm, or between about 1 μm and about 100 μm, or between about 10 μm and about 100 μm, or between about 10 μm and about 1000 μm, such as between about 100 μm and about 1000 μm.

The layered construct may comprise one or more nanoink layers. In some embodiments, the layered construct may comprise one or more nanoink layers, optionally with one or more conductive ink layers and/or one or more insulating ink layers. Thus, the methods disclosed herein include printing nanoinks to produce microscale assemblies or devices.

In some embodiments, the nanoinks may be printed to form an assembly having one or more layers. Any known printing method may be used, for example, ultrasonic, inkjet, capillary, piezoelectric jetting, electrohydrodynamic printing, direct ink transfer, flexography, gravure, spraying, pneumatic jetting, and other printing methods. Thus, as disclosed herein, “printing” may refer to any method of deposition of ink on a substrate. The ink may comprise nanoparticles or microparticles (such as rods, wires, spheres, crystalline or amorphous particles, and others). The substrate may be two-dimensional or three-dimensional.

In other embodiments, the nanoinks may be deposited by rubberstamping, flexography, or screen-printing lithography methods.

The nanoparticles or microparticles in the nanoink may have average dimensions in a range of from between about 1 nm and about 10 μm, for example, between about 1 nm and about 10 nm, or between about 1 nm and about 100 nm, or between about 10 nm and about 100 nm, or between about 10 nm and about 1000 nm, or between about 100 nm and about 1000 nm, or between about 100 nm and about 10 μm, such as between about 1000 nm and about 10 μm. In some embodiments, at least about 70%, for example, at least about 75%, about 80%, about 85%, about 90%, about 95%, about 99%, about 99.9%, about 99.99%, or about 100% of the nanoparticles or microparticles in the nanoink may have dimensions within the target range.

The nanoparticles may be formed to comprise both conductive and highly semiconductive materials, at least one carrier and may further include an insulating binder material. Highly semiconductive nanoparticles may be highly resistive. Non-limiting examples of the highly resistive nanoparticle(s) that may be used include InAs, GaAs, CdSe, CdS, ZnSe, ZnO, CdS, WSe₂, WS₂, Ag₂S, AgI, MoS₂, Cu₂S, Ag₂Se, Ag₂S₃, TiOₓ, ZrOₓ, HfOₓ, VO₂, NbO₂, and combinations thereof. Some of these materials are electrolyte cationic materials (Ag₂S, AgI, Cu₂S, Ag₂Se, Ag₂S₃); other are electrolyte anionic materials (TiOₓ, ZrOₓ, HfOₓ); yet the other are phase change metallic to insulator materials (VO₂, NbO₂).

Exemplary materials that can be used as conductive materials include, without limitation, Ag, Cu, Pt, Ni, Au, or C, for example, fullerene, carbon black, single walled carbon nanotubes (SWCNT), multi-walled carbon nanotubes (MWCNT), Ir, Ga, W, Ti, Cr, PEDOT:PSS, and combinations thereof. Frequently, Ag is used as a material for both effective size reduction and filament formation whereas inert materials (Pt, Au, Ni, SWCNT/MWCNT) used to reduce effective size of the device.

The nanoparticles may be dissolved or suspended in a carrier, to formulate an ink. Thus, in some embodiments, the ink may be a liquid. One kind of a carrier that may be used is a solvent, which may be either an organic solvent or an inorganic solvent, or a combination of both. Solvent may be any polar or non-polar. Exemplary solvents include water, toluene, ethanol, xylene, isopropyl alcohol (IPA), n-propylene alcohol, or any other organic or inorganic solvent. The solvent may be selected according to the contact properties between the nanoparticles and the surface to which the nanoink will be applied, for example, the substrate. In accordance with the present disclosure, nanoparticles may be dissolved or suspended in a carrier composition that comprise a plurality of solvents, which function as carriers or dispersants for the nanoparticles and other ink components. and may be based on factors such as solubility, compatibility, volatility, and safety. The following solvents, either used individually or in combination, may be utilized in the disclosed pigment ink compositions:

Alcohols: A class of organic compounds characterized by the presence of one or more hydroxyl (—OH) functional groups. Suitable alcohols may include, but are not limited to, methanol, ethanol, isopropanol, and butanol.

Glycols: A class of diols, characterized by the presence of two hydroxyl (—OH) functional groups. Suitable glycols may include, but are not limited to, ethylene glycol, propylene glycol, diethylene glycol, and polyethylene glycols (PEGs) of varying molecular weights. Glycol ethers: A class of solvents derived from glycols, characterized by the presence of an ether (—O—) functional group. Suitable glycol ethers may include, but are not limited to, ethylene glycol monomethyl ether, ethylene glycol monoethyl ether, propylene glycol monomethyl ether, and propylene glycol monoethyl ether.

Ketones: A class of organic compounds characterized by the presence of a carbonyl (>C═O) functional group. Suitable ketones may include, but are not limited to, acetone, methyl ethyl ketone (MEK), and cyclohexanone.

Esters: A class of organic compounds characterized by the presence of a carboxylate (—COO—) functional group. Suitable esters may include, but are not limited to, ethyl acetate, butyl acetate, and isopropyl acetate.

Alkylbenzenes: A class of aromatic hydrocarbons characterized by the presence of an alkyl group attached to a benzene ring. Suitable alkylbenzenes may include, but are not limited to, toluene and xylene.

Lactones: A class of cyclic esters characterized by the presence of a carboxylate (—COO—) functional group in a ring structure. Suitable lactones may include, but are not limited to, γ-butyrolactone and δ-valerolactone.

Water: A polar, inorganic solvent that may be utilized alone or in conjunction with other solvents to create aqueous pigment ink compositions.

Ammonia: A polar, inorganic solvent characterized by the presence of a nitrogen atom bonded to three hydrogen atoms (NH₃). Ammonia may be utilized to disperse and stabilize metal oxide nanoparticles or quantum dots in ink formulations.

Amines: A class of inorganic solvents characterized by the presence of one or more nitrogen atoms bonded to hydrogen atoms. Suitable amines may include, but are not limited to, ethylenediamine and hexamethylenetetramine. These solvents can be employed to disperse nanoparticles and quantum dots with specific surface functionalities.

Acids: Inorganic acids such as hydrochloric acid (HCl), nitric acid (HNO₃), or sulfuric acid (H₂SO₄) may be employed to disperse nanoparticles and quantum dots in ink formulations, especially when the materials require a specific pH range or an acidic environment for optimal dispersion and stability.

Alkaline solutions: Inorganic bases such as sodium hydroxide (NaOH), potassium hydroxide (KOH), or ammonium hydroxide (NH₄OH) may be utilized as solvents for dispersing nanoparticles and quantum dots in ink formulations, especially when the materials require a specific pH range or an alkaline environment for optimal dispersion and stability.

The disclosed pigment ink compositions may further comprise additional components, such as humectants, biocides, surfactants, thickeners, and other additives, as deemed necessary for specific applications. The solvent or solvent mixture employed in the pigment ink composition may be selected based on factors such as pigment dispersion stability, ink viscosity, drying time, and compatibility with the intended printing substrate.

The composition may further comprise one or more excipient, such as a wetting agent, dispersant, or surfactant. Exemplary excipients include polyamides, polyglycol sulfosuccinate, polyethers, polyesters, salts thereof, and combinations thereof. The excipient may include a polyfunctional polymer or salt thereof, e.g., alkylammonium salt thereof, or a block copolymer, for example, of affinic groups in combination with a compound having acid or amid functionalities. Other suitable excipients are also considered as being within the scope of the disclosure.

The composition may additionally comprise an insulating binder material. Exemplary insulating binder materials include derivatives of acrylates, vinyl, or other insulative materials. The binder may be included in an amount sufficient to create insulation between the contacts (electrodes) of the device, reducing or inhibiting any shorting when in use. Such amount can be determined by those having ordinary skill in the art. The binder may also serve as a scaffold and structure retainer in two-dimensional and three-dimensional assemblies. In particular, the binder may provide structural stability after the solvent evaporates. The binder may be selected to provide elastic and/or flexible properties, as desired to abide to external conditions. In some embodiments, the binder and one or more excipient, for example, surfactant, may be selected to create insulating interfaces between particles having a thickness of up to several nanometers (for example, between about 1 nm and about 10 nm, or between about 1 nm and about 5 nm). Such compositions may be used for producing Josephson-junction devices.

The composition may comprise the nanoparticles in a concentration of up to about 5% by volume, for example, between about 0.01% and about 5%, or between about 0.01% and about 4%, or between about 0.01% and about 3%, or between about 0.01% and about 2%, such as between about 0.01% and about 1% by volume In some embodiments, for example, in which the nanoparticles comprise nanowires, the composition may have about 0.01% nanowires. The composition may comprise between about 1% and about 90% by volume of the binder, for example, between about 1% and about 80%, or between about 1% and about 70%, or between about 1% and about 60%, or between about 1% and about 50%, such as between about 1% and about 40% by volume. The composition may comprise about 1%-90% by volume of the carrier, for example, between about 1% and about 80%, or between about 1% and about 70%, or between about 1% and about 60%, or between about 1% and about 50%, such as between about 1% and about 40% by volume. The composition may comprise between about 1% and about 90% by volume excipient, such as a surfactant, a dispersant, and/or a wetting agent, for example, between about 1% and about 10%, or between about 1% and about 20%, or between about 1% and about 30%, or between about 1% and about 40%, or between about 1% and about 50%, such as between about 50% and about 90% by volume.

The ink may be printed onto a substrate. The substrate may comprise any substrate (such as, plastic, silicon, silicone, glass, polyimide, and others). In some embodiments, the substrate may be an inert substrate. For instance, the substrate may be a non-conductive material. In some embodiments, the substrate may be an insulating material. In some embodiments, the substrate may be a conductive substrate. The conductive substrate may be s transparent conducting oxide (TCO) coated glass, for example, an indium tin oxide (ITO) coated glass. The coated glass substrate may replace an electrode in the layered assembly.

One exemplary method for producing nanoink devices or assemblies is inkjet printing. While inkjet printing is usually performed with conductive trace media, the methods disclosed herein may be used to manufacture the conductive traces themselves, which may be formed of nanowires and/or nanoparticles. The traces may be layered on top of each other to create microscale or nanoscale devices or assemblies.

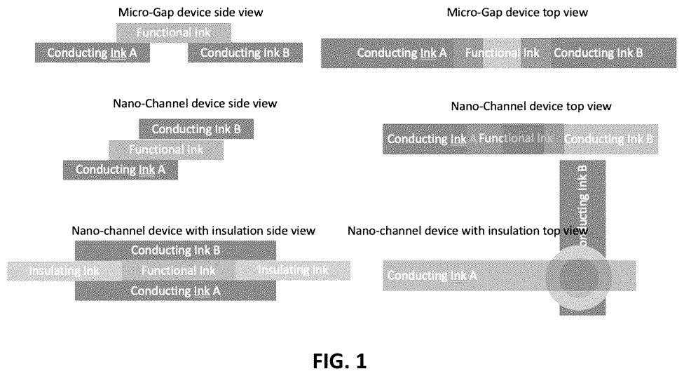

FIG. 1 is a schematic diagram showing a side view cross-section and a top view of an exemplary microscale layered assembly produced by the methods disclosed herein. In particular, the microscale assembly of FIG. 1 may be produced by a method comprising printing a nanoink having nanoparticles in a solvent onto a substrate in a layered assembly having two conductive ink layers and an optional insulating ink layer. The manufactured assemblies may be structured to develop 3D integration by methods of additive manufacturing. In 3D integration case a single or multichannel electrode arrays can be used to connect to the system. It should be noted that while the devices of FIG. 1 are three-dimensional (stacked layers), similar two-dimensional or one-dimensional devices may be produced by the methods disclosed herein by depositing adjacent rows of the material in a similar configuration. Accordingly, the assemblies disclosed herein may be in the form of nanowires, flakes, or nanoclusters.

As shown in FIG. 1, exemplary devices constructed with the nanoinks (labeled as functional ink) may be formed into a micro-gap assembly (top row) by depositing the nanoink as a layer on top of a layer having two conductive inks separated by a gap (two electrodes). In other embodiments, the method of producing the assembly of FIG. 1 can be reversed, by depositing the nanoink on the substrate and conductive inks layer on top of the nanoink. Middle row, Nano-channel devices (middle row) may be formed by depositing the nanoink over a first conductive ink (first electrode) and depositing a second conductive ink (second electrode) over the nanoink. Another configuration of a nano-channel assembly having insulation (bottom row) may be formed by depositing the nanoink between two conductive inks (electrodes) and further including an inert insulating ink in the nanoink layer, to reduce the overall section area of the assembly and prevent short circuit between opposing conductive inks (metallic counter electrodes). The inert insulating ink may comprise an insulative matrix or binder that supports the structure of the assembly.

Thus, in some embodiments, the assembly may be formed by printing or depositing the nanoink adjacent to a metallic or conductive electrode, for example, between two metallic or conductive electrodes. Such an assembly may provide resistive switching, for example, using metallization (i.e., the material may undergo conductivity change, for example, conductive filament growth) or phase transformation. In particular, the assembly may change conductivity upon application of an electric field or passage of an electric current. For instance, the application of voltage to the device may induce either a phase change that converts the device from a non-conductive or poorly conductive state to a very conductive state. The device may exhibit active properties, such as negative differential resistance. Alternatively, the application of voltage may build up a metallic filament that is served as a bridge for electron passage that turns the device into a conductor. The bridge can be destroyable either by reversing the polarity of applied electric field or by natural fluctuation or heat effects. In the phase change device, the original insulating phase may be recovered almost immediately after the electric field is removed. The conductivity change may be sufficient to be detectable, noticeable, or retainable. In some embodiments, the conductivity switch may be induced by altering known parameters of the electric field, for example, by applied current or heat.

As previously described, the assemblies disclosed herein, having microscale dimensions, may exhibit properties typical of devices having nanoscale dimensions. For example, the switching voltages typically required for a device with a thickness of tens of micrometers (for example, between about 10 μm and about 99 μm, or between about 10 μm and about 25 μm, or between about 25 μm and about 50 μm, or between about 50 μm and about 75 μm, such as between about 75 μm and 99 μm), may be between about 0.1 volt and about 1000 volts. However, the microscale assemblies disclosed herein exhibit a reduced or shortened effective length. For instance, the switching property of the microscale assemblies produced by the methods disclosed herein may be observed at much lower voltages, as low as a few volts, for example, less than about 30 volts, about 20 volts, about 10 volts, about 9 volts, about 8 volts, about 7 volts, about 6 volts, about 5 volts, about 4 volts, about 3 volts, or about 2 volts. Accordingly, such microscale assemblies may advantageously be produced by printing methods and/or be compatible with conventional CMOS devices.

Thus, in some embodiments, the assemblies may have a switching voltage below about 10 V. The devices may have a switching frequency greater than about 100 Hz. The maximum current at each assembly in an “on” state may be about 10 mA or less. The total energy for switching from an “on” state to an “off” state or backward may be 10 about μJ or less. The overall resistance of each device may be between about 10 kOhm and about 1 GOhm.

Inkjet printing of such devices may allow production of features with thicknesses above about 100 nm and size above about 1 μm. Conventional lithography may produce features as small as about 5 nm. However, neuromorphic computing does not require the size achievable by lithography. An advantage may be obtained by producing a smaller number of devices assemblies with inkjet printing to form a comparable neuromorphic computing device.

In some embodiments, the nanoink may comprise a functional (highly resistive) nanoparticle, a conductive nanoparticle, and an optional insulative material. Thus, the exemplary layered constructs may form a two-component device configuration comprising opposite electrodes and an intermediate nanoink layer including a functional pigment nanoparticle, a conductive nanoparticle, and an optional insulative matrix/binder that supports the structure but does not participate in conductivity. The metallic or conductive nanocomponents may be present in an amount sufficient to reduce the effective dimensions of the device, reducing operating field magnitudes. The conductive nanoparticles may also be included to provide a thermal coupling effect. The insulative matrix or binder may solidify to provide structural integrity to the assembly after evaporation of the solvent. Accordingly, the nanoink may be deposited on a 2D surface or cast into a 3D shape.

In accordance with the present disclosure, insulative materials may function to coalesce conductive particles and facilitate the formation of a homogeneous and uniform layer upon a substrate. Exemplary insulative or binding materials for use in conductive inks may comprise:

Various polymers, which may be employed as insulative or binding materials in functional inks, can provide mechanical stability, flexibility, and adhesion to the substrate. Non-limiting examples of such polymers include polyvinyl alcohol (PVA), polyvinylpyrrolidone (PVP), polyvinyl acetate (PVAc), polyurethane (PU), and polyacrylic acid (PAA). Cellulosic materials, such as ethyl cellulose, hydroxyethyl cellulose, and carboxymethyl cellulose, may be utilized as binders owing to their film-forming and adhesive characteristics. Silane- and siloxane-based materials may be implemented as binders in conductive inks, particularly when printing on substrates necessitating high adhesion and thermal stability. Illustrative examples of these materials encompass organofunctional silanes and silicone resins. Various resins, including, but not limited to, acrylic, epoxy, or phenolic resins, may be employed as insulative or binding materials due to their superior adhesion, mechanical strength, and thermal stability when applied to printed conductive tracks. Inorganic sol-gel materials, such as silica or alumina sols, may be used as insulative or binding materials in conductive inks. These materials offer high thermal stability, adhesion, and transparency, rendering them appropriate for specific applications, such as transparent conductive films.

In relation to the fabrication of resistive tracks, resistive nanoparticles may be employed. Common types of resistive nanoparticles may include:

Metal nanoparticles, such as silver, gold, copper, and nickel, may be utilized to print resistive tracks. By controlling particle size, concentration, and annealing conditions, the desired resistivity may be achieved. Although metal nanoparticles are typically used for printing conductive tracks, adjusting the aforementioned parameters can result in higher resistivity. Metal oxide nanoparticles, including tin oxide (SnO₂), indium tin oxide (ITO), zinc oxide (ZnO), and titanium dioxide (TiO₂), may be used to print resistive tracks. These nanoparticles exhibit semiconductive properties, and their resistivity can be tailored by modifying particle size, concentration, or doping with other elements. Carbon-based nanoparticles, such as carbon black, graphene, and carbon nanotubes (CNTs), may be employed to print resistive tracks. The resistivity of these materials can be adjusted by controlling particle size, concentration, and dispersion quality within the ink. Carbon-based nanoparticles offer the advantages of being lightweight, flexible, and chemically stable. Conductive polymers, in the form of nanoparticles, such as polyaniline (PANI), poly(3,4-ethylenedioxythiophene) polystyrene sulfonate (PEDOT:PSS), and polypyrrole (PPy), may also be used to print resistive tracks. The resistivity of these materials can be tuned by controlling the doping level, concentration, and processing conditions.

In embodiments of the present invention, the proportions of conductive and functional particles may be adjusted to achieve the desired properties, provided that the primary conductivity and percolation pathways facilitate the formation of circuits wherein elements of a series connection comprise functional particles. In the absence of such arrangements, the conductivity may be predominantly metallic and devoid of the intended functionality.

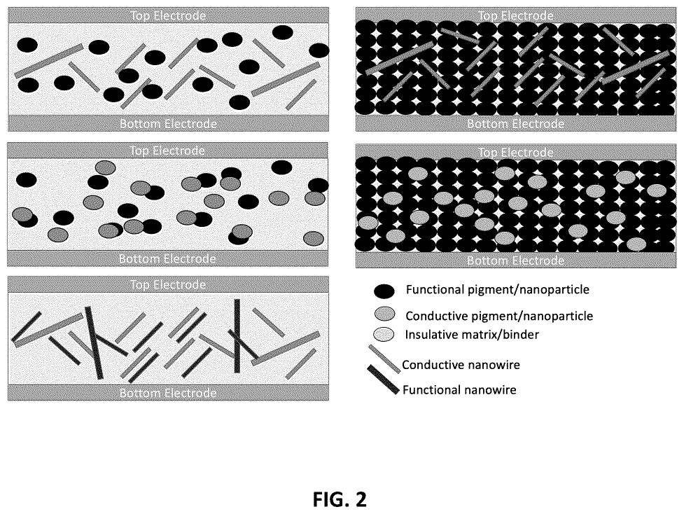

Side cross-sectional views of two exemplary layered constructs are shown in FIG. 2. In the first configuration (left column of FIG. 2) each of the functional pigment nanoparticle and conductive nanoparticle is present in an amount below a percolation threshold. However, when the nanoparticles are combined, the percolation threshold is reached. Thus, the assembly in the left column may have a percolation threshold above 0.5. In this embodiment, the effective length of the device (exhibited as required switching voltage) is reduced to a nanoscale size, for example, as small as a 10 nm or less, and can be switched with voltages below 30 V.

In the second configuration, (right column of FIG. 2) the functional nanoparticle is present in an amount above the percolation threshold. In particular, in the embodiment of the right column, the percolation probability is close to 1 (100%). The conductive nanoparticles (nanowires) are present in an amount below the percolation threshold (i.e., below 50% of percolation probability). In this embodiment, the effective length of the device (exhibited as required switching voltage) is significantly reduced while the functional material is visually present.

As mentioned above and further discussed herein, percolation threshold refers to the percolation probability as a function of normalized volume/surface fraction of components when the percolation probability is 0.5 or 50% (FIG. 3). A percolation threshold of 0.5 may generally correspond with a sample having an amount of nanoparticles sufficient to produce a conductive ink, for example, if the binder or filler matrix were formed of a conductive metallic particle. In some embodiments, nanoscale advantages are achieved with macroscale dimensioned devices in binary or non-binary systems when all nanoparticle components are present in an amount below the percolation threshold. In such embodiments, when the nanoparticle components are combined, the overall composition is above the percolation threshold.

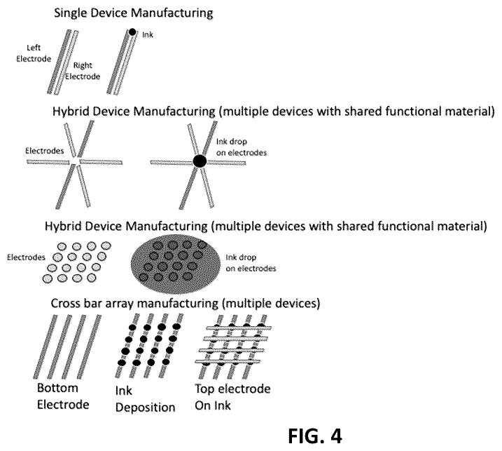

Exemplary devices that can be produced by the methods disclosed herein are shown in FIG. 4. In FIG. 4, single devices are shown in the top row, hybrid devices are shown in the lower rows. The single device is shown with adjacent electrodes. Such devices are typically 1-5 μm in length. The hybrid devices may include shared functional material connected by a nanoink layer. The second-row hybrid device includes electrode rods connected by a central nanoink drop. The third-row hybrid device includes electrode dots (arranged in an array) connected by a nanoink layer. The fourth-row hybrid device includes electrodes positioned in a cross-bar array with nanoink dots between top and bottom arrays of electrodes. Accordingly, the layered constructs manufactured herein may comprise a single electrode pair or a plurality of electrode pairs (hybrid devices). The hybrid devices typically exhibit sparse properties with shared states that are beneficial in certain kinds of computation.

The following examples are provided to further elucidate the advantages and features of the present invention but are not intended to limit the scope of the invention.

### EXAMPLES

### Example 1. Production of a Two-Dimensional Conductive Assembly

Exemplary proof of concept devices or constructs as disclosed herein may be produced with a piezoelectric jetting printer (distributed by Sonoplot Inc., Middleton, WI).

There are many ways of constructing a two-dimensional functional device (as shown in FIGS. 1-2) with the nanoink formulations disclosed herein. For example, to make a nano-channel device, the surface of the substrate may optionally first be treated to be cleaned from contaminants. The conductive ink may be applied in a desired quantity. The functional or highly resistive ink may be applied on top of the conductive ink. The solvent may be allowed to evaporate forming a solid construct. After drying, another conductive ink layer is applied on top of the dried construct, creating a conductive bridge.

A microchannel device can be constructed by either applying conductive tracks on the surface of the substrate first and then applying a nanoink over the conductive tracks. Alternatively, the microchannel device may be constructed by applying a nanoink on the surface of the substrate and drawing conductive channels on top of the ink.

### Example 2. Resistive Switch Voltage

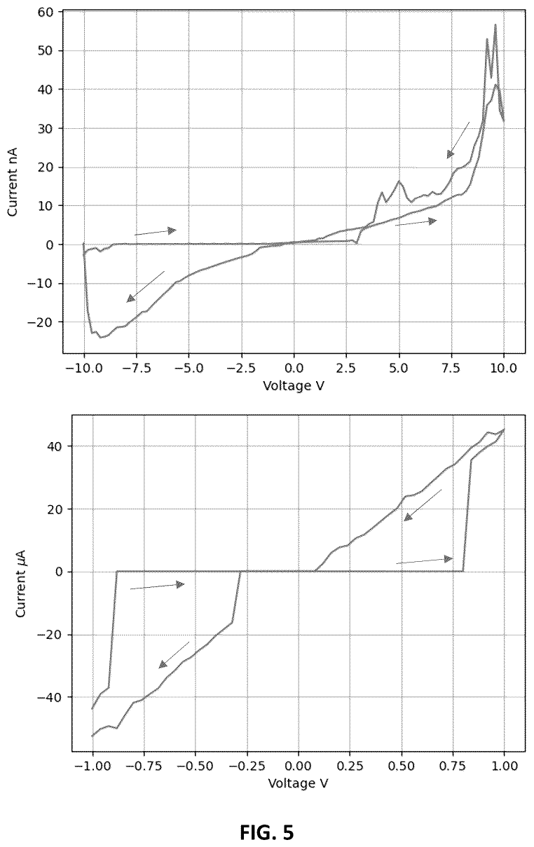

FIG. 5 includes graphs showing characteristics of voltage driven devices with a 15 μm gap. A layered assembly comprising a first conductive layer, a nanoink layer, and a second conductive layer was produced. Briefly, a first ink having conductive nanoparticles was deposited on a clean microscope glass slide via a micro-dispenser and sintered at 130° C. for 5 minutes to form a 1 μm thick layer of conductor as the first electrode. A composite nanoink having highly resistive and conductive nanoparticles was deposited over the first conductive layer as a viscous droplet and also dried at temperature of 130° C. for 10 minutes to evaporate solvents, reduce the volume, and bring contents to above percolation concentration. Finally, a second layer of the conductive ink was deposited on top of the dried assembly as the second electrode and sintered at 130° C. for 5 minutes. The resulting layered assembly had a 15 μm gap between electrode layers filled with functional solid electrolyte material.

The above procedure can be produced with a conductive surface, such as glass coated with indium tin oxide (ITO), eliminating one layer of conductive ink.

To characterize the device, a single triangle voltage cycle was sent to the device. The device had an efficient thickness much smaller than the physical dimension of the device (in accordance with the embodiments disclosed herein). The device was compared to a similar device having only functional nanoparticles and lacking the composite nanoink as a control.

As shown in FIG. 5, resistive switching of the control assembly with single component functional nanoparticles (top) required high switching voltages to drive relatively small current of below 60 nA. By comparison (bottom), the assembly including a composite nanoink (i.e. conductive NPs with functional NPs) as disclosed herein required voltages below 1 V to drive currents above 40 μA. Accordingly, the nanoinks disclosed herein produce layered devices exhibiting reduced switching voltages and higher currents that permit simpler integration with conventional CMOS infrastructure.

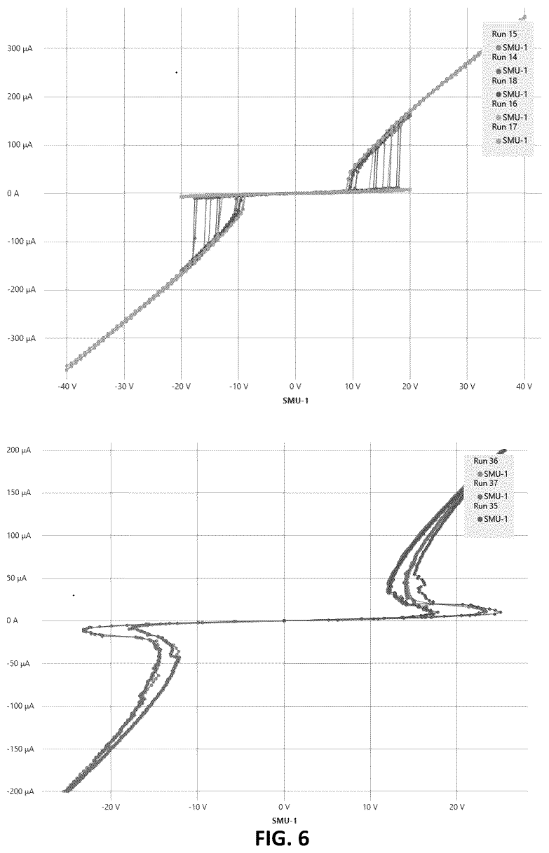

FIG. 6 includes graphs showing resistive switching of a neuroresistive ink with a nanoscale phase change material, such as VO₂ and NbO₂. A voltage driven field induced phase change (unipolar switching), as shown by the data presented in the top graph. A current driven resistive switch exhibited Negative Differential Resistance, as shown by the data presented in the bottom graph. Accordingly, the device was shown to be an active electronic device.

In one embodiment of the present invention, a representative composition may include composition of Ag₂Se/Ag and Carrier composition that can be created in the following three steps:

Step 1. Prepare 2% by vol of silver selenide (Ag₂Se) nanowires, having an average diameter of 100 nm and an average length of 10 μm, and 0.5% by volume of metallic silver (Ag) nanowires, having an average diameter of 50 nm and an average length of 10 μm, called a nanoparticle mixture. Then dispersion of the mixture in an organic carrier is performed as follows.

Step 2: Preparing the varnish, may include polyvinylpyrrolidone (PVP) varnish (20%) constituting 30% of the total composition. Preparing the ink formula by mixing all components, which may include:
a. Nanoparticle mixture (up to 50% by vol for spherical particles or less than 0.01% for high aspect ratio particles), b. PVP varnish as prepared in step 1 (30% of the total composition), c. Dispersant and stabilizer (0.5%), d. n-propanol (52%), e. Dimethyl adipate (2.5%), and f. N-methyl-2-pyrrolidone (NMP) (5%).

Step 3: Includes mixing all components under gentle stirring in an orbital planetary mixer under vacuum with subsequent sonication.

Switching Matrix and Memristive Circuits

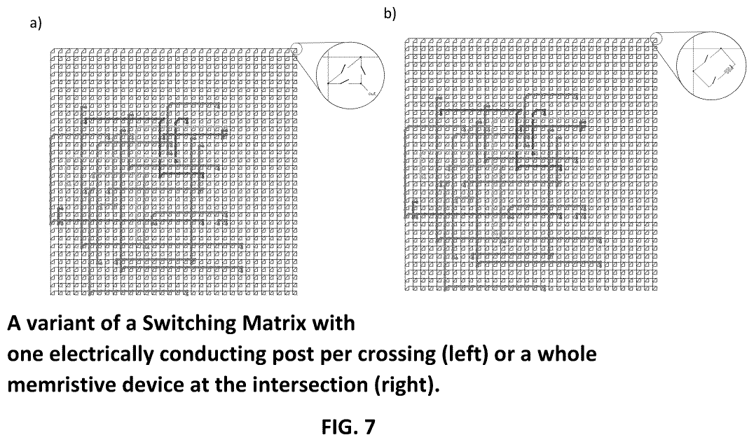

A variant of switching matrix as shown in FIG. 7, where either each intersection of horizontal and vertical bus lines is decorated with three switches connected to a controller (not shown) and one output. Where in such configuration each output of the switching matrix is connected to one or several elements of the circuit (FIG. 7, left). This configuration allows terminal of the element to be connected to horizontal, vertical buses or disconnected to avoid sneaky currents.

Or 2^{nd} configuration as shown on the FIG. 7 (right) where each intersection of the horizontal and vertical bus lanes is decorated with two switches and a memristor. The top switch is to bypass memristor and utilize bus for connectivity and for circuit configurations and another switch connected in series with a memristor to connect memristor to a circuit or disconnect it. Multiple other variants are possible, however all of them serve the same purpose of constructing arbitrary circuits as explained below.

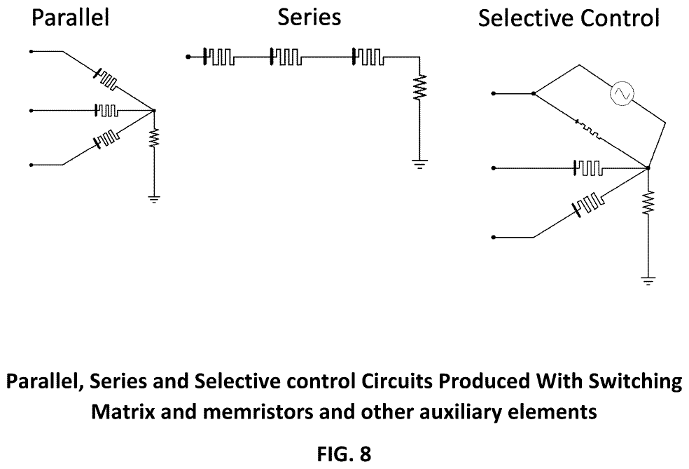

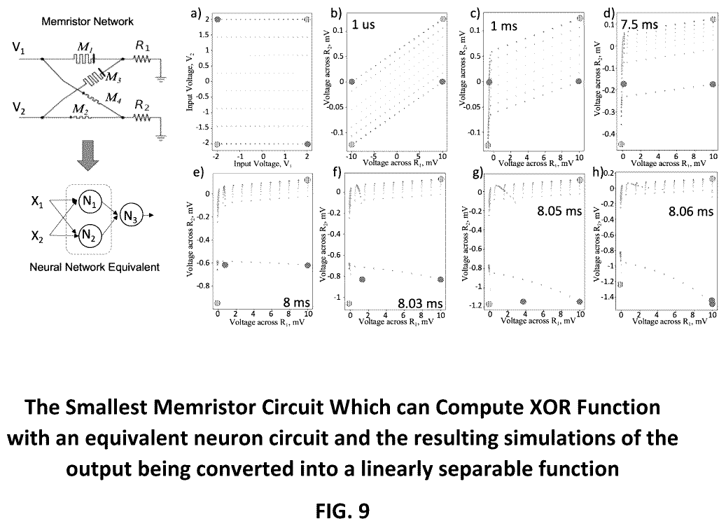

Given a matrix with memristive or other elements connected in such as described above way that one terminal of the element is connected to matrix post or output at each intersection, using optimal path search or quantum methods one can find a configuration of the switches states that would assemble wide range of circuits such as shown in FIG. 8. These circuits can form basic computing elements such as summation and integration and even logical gates as shown in FIG. 9 where an XOR solver is shown.

In particular, the XOR solver shown below is made of 4 memristors and 2 resistors which are assembled in a modified Wheatstone bridge configuration and have two inputs and two outputs. The inputs are voltages that represent truth table inputs of the logical gate, whereas the outputs are currents or voltages harvested from the two output resistors. As shown in FIG. 9 the inputs are 4 voltage configuration each labeled as circles with diagonal or vertical pattern, denoting true or false as expected output. At first it is not linearly separable, i.e. there is no straight line that can be drawn to separate circles with vertical and diagonal fill pattern. However as shown in FIG. 9, the outputs evolve due to the properties of memristor temporal dynamics that result in linear separation of circles with diagonal and vertical fill pattern and hence reducing the complexity of XOR problem from linearly inseparable to linearly separable.

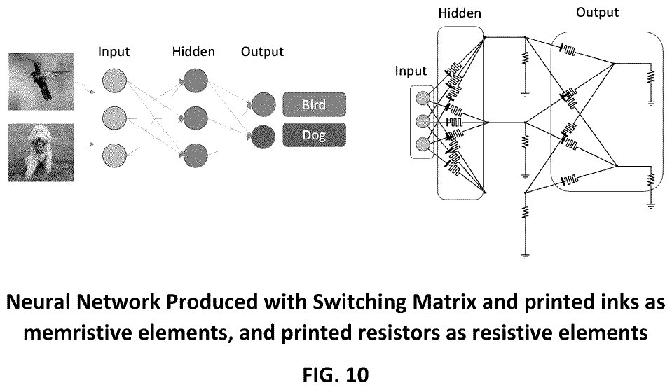

The switching matrix permits construction of more sophisticated circuits with memristors and other elements such as neural networks, as shown in FIG. 10. The circuit relies on memristors connected in series or in parallel where each memristive element is comprised of 2d or 3d composite material mentioned above.

Although the invention has been described with the reference to the above examples, it will be understood that modifications and variations are encompassed within the scope and the spirit of the invention. Accordingly, the invention is limited only by the following claims.

What is claimed is:

1. A composition comprising at least one semiconductive nanoparticle, at least one electronically conductive nanoparticle, and at least one carrier, wherein the composition is formulated as an ink.

2. The composition of claim 1, wherein the semiconductive nanoparticle is highly resistive.

3. The composition of claim 1, wherein the conductive nanoparticle(s) is selected from the group consisting of Ag, Cu, Pt, Ni, Au, C, Ir, Ga, W, Ti, Cr, PEDOT:PSS and any combination thereof.

4. The composition of claim 1, further comprising an insulating binder material.

5. The composition of claim 2, wherein the highly resistive nanoparticle(s) is selected from the group consisting of InAs, GaAs, CdSe, CdS, ZnSe, ZnO, CdS, WSe₂, WS₂, Ag₂S, AgI, MoS₂, Cu₂S, Ag₂Se, Ag₂S₃, TiOₓ, ZrOₓ, HfOₓ, VO₂, NbO₂, and any combination thereof.

6. The composition of claim 2, wherein each of the highly resistive nanoparticle(s) and the conductive nanoparticle(s) is present in an amount below a percolation threshold of the composition.

7. The composition of claim 2, wherein the highly resistive nanoparticle and the conductive nanoparticle are each independently in the form of a rod, wire, sphere, crystalline particle, or amorphous particle.

8. The composition of claim 2, wherein the carrier is selected from a group consisting of at least one organic solvent, at least one inorganic solvent, and any combination thereof.

9. A method of manufacturing a microscale assembly comprising printing at least one layer of the composition of claim 1 onto a substrate adjacent at least one conductive electrode to form the microscale assembly.

10. The method of claim 9, wherein printing the at least one layer of the composition between two conductive electrodes.

11. The method of claim 9, wherein the substrate is a non-conductive material selected from the group consisting of plastic, silicon, silicone, glass, and polyimide.

12. The method of claim 9, wherein the substrate is a conductive coated glass.

13. The method of claim 9, wherein the microscale assembly forms at least one component of a neuromorphic computing chip, a photonic or chemical sensor, or a quantum computation chip.

14. The method of claim 9, wherein the assembly has a thickness of between about 0.1 and about 99 μm.

15. The method of claim 9, wherein the assembly experiences resistive switching responsive to an applied electric field having a voltage of less than about 30 volts.

16. The method of claim 9, wherein the assembly has a thickness of between about 10 and about 99 μm and experiences resistive switching responsive to an applied electric field having a voltage of less than about 30 volts.

17. The method of claim 9, wherein the assembly is selected from the group consisting of a one-dimensional assembly, a two-dimensional assembly, and a three-dimensional assembly.

18. A switching matrix comprising a plurality of intersecting conductive bars, with one or more switching elements located at each intersection, wherein each switching element is configured to facilitate a connection between the intersecting bars or to establish a connection to a terminal or a device of interest.
